(19) United States
(12) Patent Application Publication
(10) Pub. No.: US 2012/0032344 A1
(43) Pub. Date: Feb. 9, 2012

(54) SEMICONDUCTOR DEVICE AND METHOD OF MANUFACTURING SEMICONDUCTOR DEVICE

(75) Inventor: Tatsuya USAMI, Kanagawa (JP)

(73) Assignee: Renesas Electronics Corporation

(21) Appl. No.: 13/204,163

(22) Filed: Aug. 5, 2011

(30) Foreign Application Priority Data
Aug. 9, 2010 (JP) 2010-178684

(51) Int. Cl. H01L 23/48; H01L 21/28

(52) U.S. Cl. 257/774; 438/652; 257/E23.011; 257/E21.158

(57) ABSTRACT

A plurality of interconnects is, for example, a plurality of Cu interconnects, extending parallel to each other. Sidewall insulating films are formed at the sidewalls of each of a plurality of interconnects. An air gap is formed between each of a plurality of interconnects, and is located between a plurality of sidewall insulating films. The insulating film is formed on a plurality of interconnects, a plurality of sidewall insulating films, and the air gap. A via passes through the insulating film, and is connected to any of the interconnects. The sidewall insulating film is formed of a material having an etching rate lower than that of the insulating film in the conditions in which the insulating film is etched.

This application is based on Japanese patent application No. 2010-178684, the content of which is incorporated hereinto by reference.

### BACKGROUND

1. Technical Field

The invention relates to a semiconductor device having an air gap between a plurality of interconnects and a method of manufacturing the semiconductor device.

2. Related Art

Miniaturization of semiconductor devices has progressed, and as a result, the distance between interconnects adjacent to each other has become narrower. When the distance between the interconnects becomes narrow, the parasitic capacitance occurring therebetween increases, and the signal transfer rate becomes slow. In order to solve such a problem, reducing the dielectric constant between the interconnects by providing an air gap between the adjacent interconnects has recently been examined (see, for example, S. Uno et al., “Dual Damascene Process for Air-Gap Cu Interconnects Using Conventional CVD Films as Sacrificial Layers”, Proceedings for IITC 2005).

### SUMMARY

Generally, since semiconductor devices have a multilayer interconnect structure, each interconnect is connected to an upper-layer interconnect through a via except for an uppermost interconnect layer. The via is formed by forming a connection hole in an insulating film and burying a conductor in the connection hole. As a result of examination by the inventor, it was found that when misalignment occurs in the connection hole, the connection hole and the air gap are connected to each other at the time of forming the connection hole, and thus defective burial of the conductor has occurred in the connected portion. For this reason, it is necessary to prevent the connection of the connection hole and the air gap to each other.

In one embodiment, there is provided a semiconductor device including: a plurality of interconnects extending parallel to each other; sidewall insulating films formed at sidewalls of each of the plurality of interconnects; an air gap, formed between each of the plurality of interconnects, which is located between a plurality of sidewall insulating films; an insulating film formed over the plurality of interconnects, the plurality of sidewall insulating films and the air gap; and a via, passing through the insulating film, which is connected to any of the interconnects, wherein the sidewall insulating film is formed of a material having an etching rate lower than that of the insulating film in the conditions in which the insulating film is etched.

According to the invention, the sidewall insulating films are formed at the sidewalls of the interconnects, and the air gap is located between the sidewall insulating films. The sidewall insulating film is formed of a material having an etching rate lower than that of the insulating film in the conditions in which the insulating film is etched. For this reason, even when misalignment occurs in the via, the via hardly passes through the sidewall insulating film, and thus it is possible to prevent the connection of the via to the air gap.

In another embodiment, there is provided a method of manufacturing a semiconductor device, including: forming a second insulating film over a first insulating film; forming a plurality of interconnect trenches extending parallel to each other on the second insulating film, and forming an altered film by altering sidewalls of the plurality of interconnect trenches; forming a plurality of interconnects by burying a conductive film in the plurality of interconnect trenches; removing the second insulating film by etching, and leaving the altered film in sidewalls of the interconnects; forming an insulating film over the first insulating film, the plurality of interconnects, and the altered film, and forming an air gap between the plurality of interconnects; and forming a via, passing through the insulating film, which is connected to any of the interconnects, wherein the altered film is formed of a material having an etching rate lower than that of the insulating film in the conditions in which the insulating film is etched.

According to the invention, even when misalignment occurs in the via, it is possible to prevent the connection of the via to the air gap.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view illustrating a configuration of a semiconductor device according to a first embodiment.

FIGS. 2A and 2B are cross-sectional views for explaining a method of manufacturing the semiconductor device shown in FIG. 1.

FIGS. 3A and 3B are cross-sectional views for explaining the method of manufacturing the semiconductor device shown in FIG. 1.

FIGS. 4A and 4B are cross-sectional views for explaining the method of manufacturing the semiconductor device shown in FIG. 1.

FIGS. 5A and 5B are cross-sectional views for explaining the method of manufacturing the semiconductor device shown in FIG. 1.

FIG. 6 is a cross-sectional view for explaining the method of manufacturing the semiconductor device shown in FIG. 1.

FIGS. 7A and 7B are diagrams for explaining a reason for which a sidewall insulating film remains in a process shown in FIG. 4B.

FIGS. 8A and 8B are diagrams illustrating a reference example, and are diagrams illustrating a molecular structure of the sidewall insulating film in which organopolysiloxane is used as the sidewall insulating film.

FIGS. 9A and 9B are cross-sectional views illustrating the method of manufacturing the semiconductor device according a second embodiment.

FIGS. 10A and 10B are cross-sectional views illustrating the method of manufacturing the semiconductor device according to the second embodiment.

FIGS. 11A and 11B are cross-sectional views illustrating the method of manufacturing the semiconductor device according to the second embodiment.

FIG. 12 is a cross-sectional view illustrating the method of manufacturing the semiconductor device according to the second embodiment.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, the embodiment of the invention will be described with reference to the accompanying drawings. In all the drawings, like elements are referenced by like reference numerals and descriptions thereof will not be repeated.

### First Embodiment

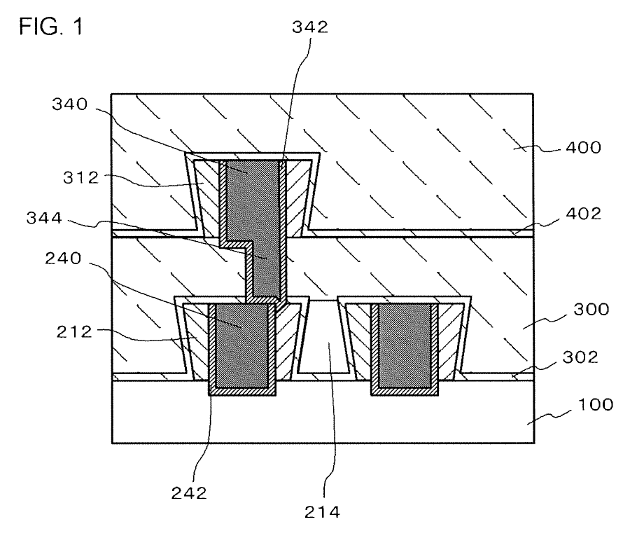

FIG. 1 is a cross-sectional view illustrating a configuration of a semiconductor device according to a first embodiment. The semiconductor device includes a plurality of interconnects 240, sidewall insulating films 212, an air gap 214, an insulating film 302, and a via 344. A plurality of interconnects 240 is, for example, a plurality of Cu interconnects, extending parallel to each other. The sidewall insulating films 212 are formed at the sidewalls of a plurality of each of the interconnects 240. The air gap is formed between a plurality of each of the interconnects 240, and is located between a plurality of sidewall insulating films 212. The insulating film 302 is formed on a plurality of interconnects 240, a plurality of sidewall insulating films 212, and the air gap 214. The via 344 passes through the insulating film 302, and is connected to any of the interconnects 240. The sidewall insulating film 212 is formed of a material having an etching rate lower than that of the insulating film 302 in the conditions in which the insulating film 302 is etched. Hereinafter, a detailed description will be made.

The interconnect 240 is formed on an insulating film 100 (first insulating film) serving as an underlying film. Meanwhile, the lower portion of the interconnect 240 intrudes in the insulating film 100 due to a manufacturing process. The sidewall insulating film 212 is formed on the insulating film 100 along the sidewall of the interconnect 240. The upper end of the sidewall insulating film 212 is flat, and is larger in width than the lower end of the sidewall insulating film 212. In addition, the upper surfaces of the sidewall insulating film 212 and the interconnect 240 are formed to be coplanar, for example, flush with each other. The sidewall insulating film 212 is, for example, a film obtained by oxidizing a hydrogenated siloxane film, but may be a film obtained by doping a SiO₂ film with an impurity such as boron.

The insulating film 302 is provided as an etching stopper film, and is formed on the insulating film 100, a plurality of interconnects 240, a plurality of sidewall insulating films 212 and the air gap 214. The insulating film 302 is, for example, a SiC film, a SiCN film, or a SiCO film.

An insulating interlayer 300 is formed on the insulating film 302. The insulating interlayer 300 is formed of a material having a dielectric constant lower than that of silicon oxide, for example, of SiCOH.

An interconnect 340, a sidewall insulating film 312, an insulating film 402, and an insulating interlayer 400 are formed on the insulating interlayer 300. The materials of the interconnect 340, the sidewall insulating film 312, the insulating film 402, and the insulating interlayer 400 are the same as the materials of the interconnect 240, the sidewall insulating film 212, the insulating film 302, and the insulating interlayer 300.

The interconnect 340 is formed integrally with the via 344 by a dual damascene method. The via 344 is connected to any of the interconnects 340. Meanwhile, the interconnects 240 and 340 include barrier metal films 242 and 342 on the lateral side and the bottom thereof.

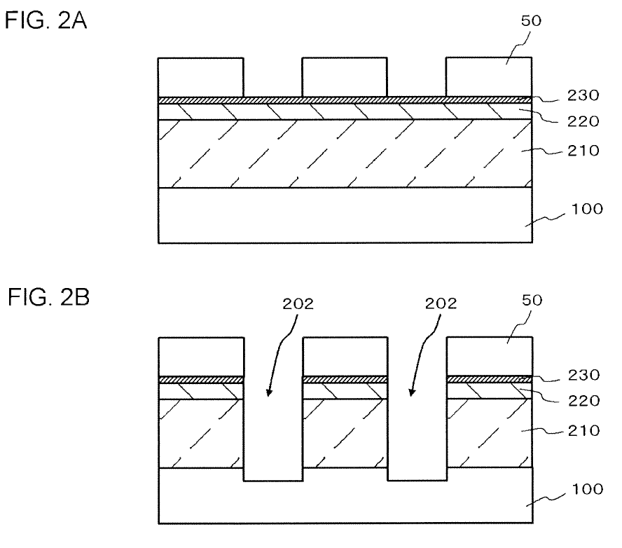

Next, a method of manufacturing the semiconductor device shown in FIG. 1 will be described with reference to FIGS. 2 to 6. An outline of the method of manufacturing the semiconductor device is as follows. First, an insulating film 210 (second insulating film) is formed on the insulating film 100. Next, a plurality of interconnect trenches 202 extending parallel to each other is formed in the insulating film 210, and the sidewall insulating films 212 are formed by altering the sidewalls of a plurality of interconnect trenches 202. Next, a plurality of interconnects 240 is formed by burying a conductive film in the plurality of interconnect trenches 202. Next, the insulating film 210 is removed by etching, and the sidewall insulating film 212 is left on the sidewall of the interconnect 240. Next, the insulating interlayer 300 is formed on the insulating film 100, a plurality of interconnects 240, and the sidewall insulating film 212, and the air gap 214 is formed between a plurality of interconnects 240. Next, the via 344 is formed. Hereinafter, a detailed description will be made.

First, as shown in FIG. 2A, a transistor is formed on a substrate (not shown). Next, the insulating film 100 is formed on the substrate. One or a plurality of interconnect layers may be formed between the substrate and the insulating film 100. The insulating film 100 is, for example, a SiCOH film, and is formed by, for example, a CVD method. Next, the insulating film 210, an insulating film 220, and an antireflection film 230 are formed on the insulating film 100. The insulating film 210 is, for example, a hydrogenated polysiloxane film, and is formed by, for example, application and burning. As a hydrogenated polysiloxane, for example, a ladder-type hydrogenated polysiloxane is used. However, the insulating film 210 may be a silicon oxide film, and may be a porous hydrogenated polysiloxane film. The insulating film 220 is, for example, a silicon oxide film, and is formed by a CVD method. When the insulating film 210 is a silicon oxide film, the insulating film 220 may be omitted. Next, a resist pattern 50 is formed on the antireflection film 230.

Next, as shown in FIG. 2B, the antireflection film 230, and the insulating films 220 and 210 are dry-etched in this order using the resist pattern 50 as a mask. Thereby, the interconnect trenches 202 are formed in the insulating films 220 and 210. In this process, fluorocarbon and oxygen are contained in an etching gas at the time of etching the insulating film 210. This allows selectivity to be given to the insulating film 210 and the insulating film 100.

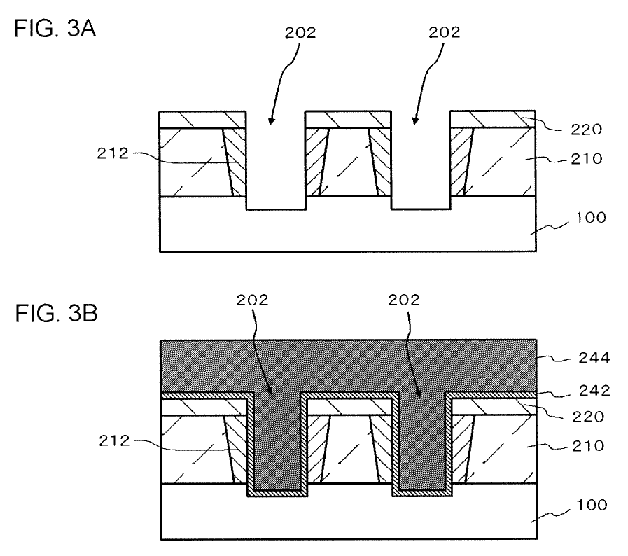

Next, as shown in FIG. 3A, the resist pattern 50 and the antireflection film 230 are removed. In this removal process, oxygen plasma is used. For this reason, the portion facing the interconnect trench 202 in the insulating film 210 is oxidized, and becomes the sidewall insulating film 212. Meanwhile, the number of active species of oxygen plasma decreases with the intrusion below the interconnect trench 202. For this reason, the upper end of the sidewall insulating film 212 is larger in width than the lower end thereof. Meanwhile, when the insulating film 210 is a silicon oxide film, the sidewall insulating film 212 is formed by ion implantation of boron.

Next, as shown in FIG. 3B, the barrier metal film 242 is formed on the insulating film 220, and the sidewall and the bottom of the interconnect trench 202 by a sputtering method. The barrier metal film 242 is, for example, a laminated film in which a TaN film and Ta are laminated in this order from the bottom. Next, a seed film (not shown) is formed on the barrier metal film 242 by a sputtering method. Next, a metal film 244 is formed on the barrier metal film 242 by performing plating using the seed film as a seed.

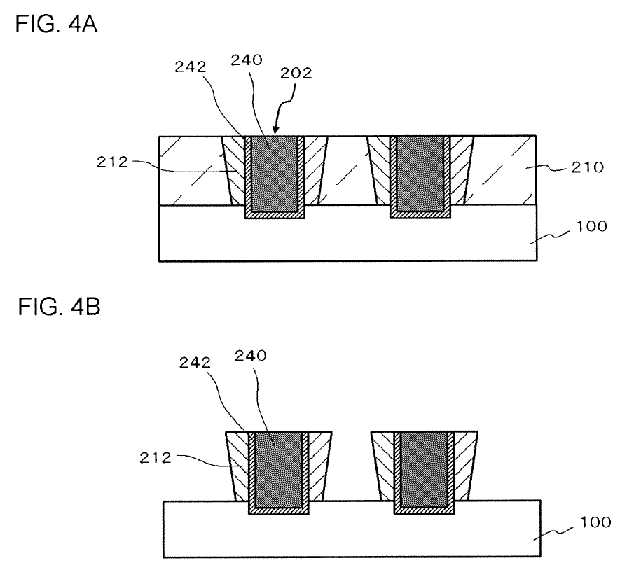

Next, as shown in FIG. 4A, after heat treatment is performed on the metal film 244, the metal film 244 and the barrier metal film 242 which are located above the insulating film 220 are removed by a CMP method. At this time, the insulating film 220 is also removed. Thereby, the interconnect 240 is buried in the insulating film 210. In this process, the upper surface of the sidewall insulating film is formed to be coplanar with the upper surface of the interconnect 240.

Next, as shown in FIG. 4B, the insulating film 210 is removed by wet etching. As an etchant, for example, a dilute hydrogen fluoride (DHF) solution is used. As mentioned above, the sidewall insulating film 212 is formed by oxidizing the insulating film 210. For this reason, the sidewall insulating film 212 has a slower etching rate than the insulating film 210. As a result, the sidewall insulating film 212 is not etched and remains in the sidewall of the interconnect 240.

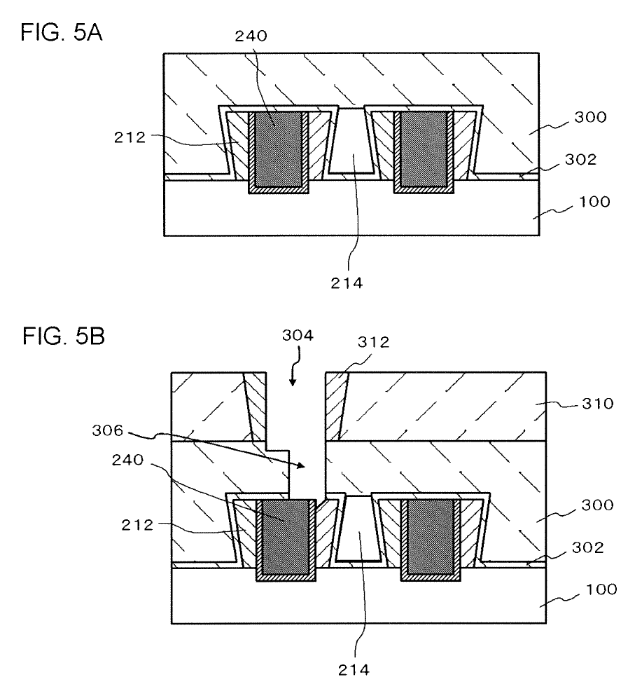

Next, as shown in FIG. 5A, the insulating film 302 is formed on the insulating film 100, a plurality of interconnects 240, and the sidewall insulating film 212. Next, the insulating interlayer 300 is formed on the insulating film 302. The insulating interlayer 300 is formed, by for example, a CVD method. In this process, the insulating film 302 is not intruded between the sidewall insulating films 212, and as a result, the air gap 214 is formed.

Next, as shown in FIG. 5B, an insulating film 310 is formed on the insulating interlayer 300 by a CVD method. A material of the insulating film 310 is the same as that of the insulating film 210. Next, an interconnect trench 304 and a connection hole 306 are formed in the insulating film 310. A method of forming them is the same as the process of forming the interconnect trench 202 in the insulating film 210. For this reason, the sidewall insulating film 312 is formed at the lateral side of the interconnect trench 304.

Meanwhile, the bottom of the connection hole 306 passes through the insulating film 302. For this reason, in the final process of the dry etching process for forming the connection hole 306, an etching gas has a composition for etching the insulating film 302.

In this process, misalignment may occur in the connection hole 306 and the interconnect trench 304. On the other hand, in the embodiment, the sidewall insulating film 212 is formed at the sidewall of the interconnect 240. For this reason, in order to connect the air gap 214 and the connection hole 306 to each other, the sidewall insulating film 212 is required to be etched in the process of forming the connection hole 306. On the other hand, the sidewall insulating film 212 is formed by oxidizing the insulating film 210, and thus is difficult to etch in the conditions in which the insulating film 302 is etched. For this reason, even when misalignment occurs in the connection hole 306 and the interconnect trench 304, it is possible to prevent the connection of the air gap 214 to the connection hole 306.

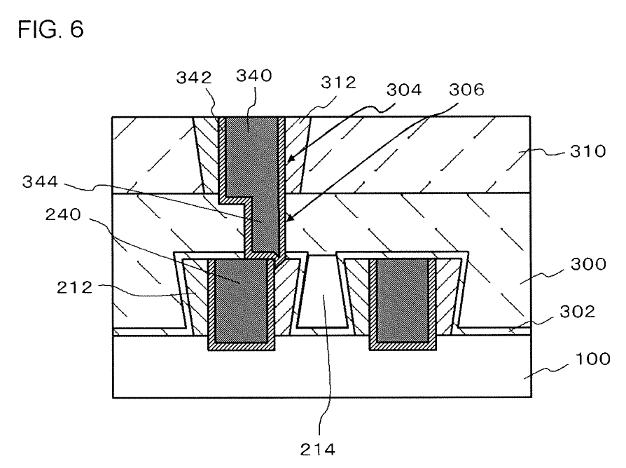

Next, as shown in FIG. 6, the barrier metal film 342 is formed in the connection hole 306 and the interconnect trench 304. Next, the via 344 is buried in the connection hole 306, and the interconnect 340 is buried in the interconnect trench 304. A method of forming the barrier metal film 342, the via 344, and the interconnect 340 is the same as the method of forming the barrier metal film 242 and the interconnect 240.

Thereafter, as shown in FIG. 1, the insulating film 310 is removed. In this process, the sidewall insulating film 312 is not etched, and remains on the sidewall of the interconnect 340. Thereafter, the insulating film 402 is formed on the insulating interlayer 300, the interconnect 340, and the sidewall insulating film 312. Next, the insulating interlayer 400 is formed on the insulating film 402.

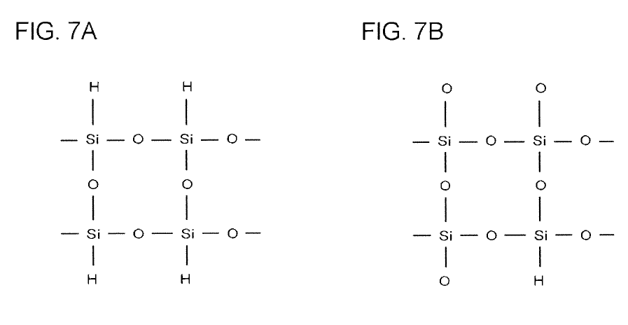

FIGS. 7A and 7B are diagrams for explaining a reason for which the sidewall insulating film 212 remains in the process shown in FIG. 4B. As shown in FIG. 7A, in the hydrogenated siloxane film, a portion of Si—O is replaced by Si—H. When the hydrogenated siloxane film is treated with oxygen plasma, as shown in FIG. 7B, at least a portion of Si—H is replaced by Si—O due to active oxygen (for example, oxygen ion or active oxygen) in the oxygen plasma. At this time, it is difficult to form a dangling-bond in Si. In addition, Si—O has a bond strength stronger than that of Si—H. As mentioned above, the sidewall insulating film 212 has a number of Si—H bonds smaller than that of the insulating film 210, and thus is difficult to etch even in the conditions in which the insulating film 210 is etched.

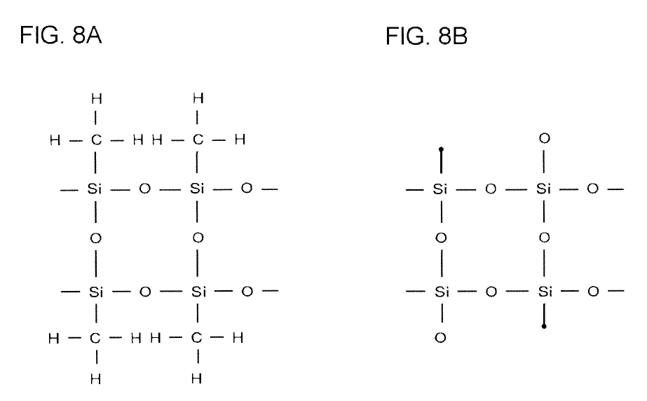

FIGS. 8A and 8B are diagrams illustrating a reference example, and are diagrams illustrating a molecular structure of the sidewall insulating film 212 in which organopolysiloxane is used as the insulating film 210. As shown in FIG. 8A, in the organopolysiloxane, a portion of Si—O bonds is replaced by Si—CH₃ bonds. When the organopolysiloxane is treated with oxygen plasma, as shown in FIG. 8B, a portion of the Si—CH₃ bonds is replaced by the Si—O bonds, but a dangling-bond is also formed in Si. For this reason, the sidewall insulating film 212 is easily etched in the conditions in which the insulating film 210 is etched. In addition, even when the sidewall insulating film 212 remains, the sidewall insulating film 212 easily absorbs water, which results in an increase in the capacitance between the interconnects.

Next, operations and effects of the embodiment will be described. According to the embodiment, the sidewall insulating film 212 is formed at the sidewall of the interconnect 240. The air gap 214 is located between the sidewall insulating films 212. On the other hand, since the sidewall insulating film 212 is formed of a material different from that of the insulating film 302 and has a film quality different from that of insulating film 302, it has an etching rate lower than that of the insulating film 302 in the conditions in which the insulating film 302 is etched. For this reason, even when misalignment occurs in the connection hole 306 and the interconnect trench 304, it is possible to prevent the connection of the air gap 214 to the connection hole 306.

### Second Embodiment

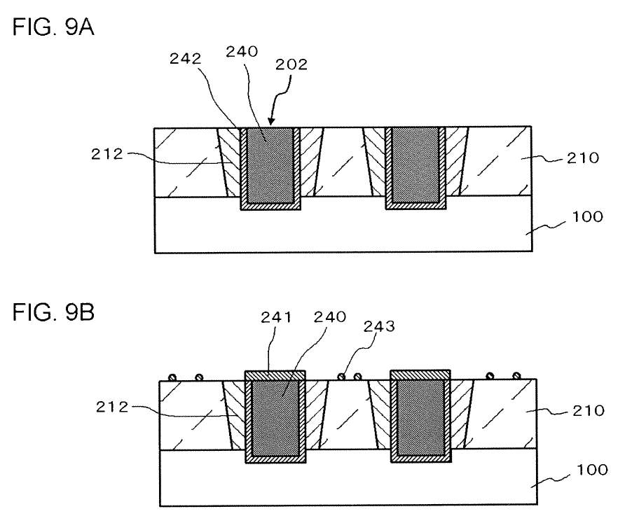

FIGS. 9A to 12 are cross-sectional views illustrating a method of manufacturing the semiconductor device according to a second embodiment. The semiconductor device manufactured by the embodiment has the same configuration as that of the semiconductor device according to the first embodiment, except that it includes cap metal films 241 and 341 on the interconnects 240 and 340.

First, a transistor is formed on a substrate (not shown). Next, the insulating film 100, the insulating film 210, the interconnect trench 202, the sidewall insulating film 212, the barrier metal film 242, and the interconnect 240 are formed on the substrate. A method of forming them is the same as that of the first embodiment.

Next, as shown in FIG. 9B, the cap metal film 241 is formed on the interconnect 240 using a selective CVD method. The cap metal film 241 is, for example, W, but may be Co, Si, Ag, Mg, Be, Zn, Pd, Cd, Au, Hg, Pt, Zr, Ti, Sn, Ni, Fe, CoWP, or CoWB. In addition, when a metal, such as Ni, capable of being formed by an electroless plating method is used as the cap metal film 241, the cap metal film 241 may be formed by the electroless plating method. In this process, erroneously selected metals 243 may be formed on the insulating film 210.

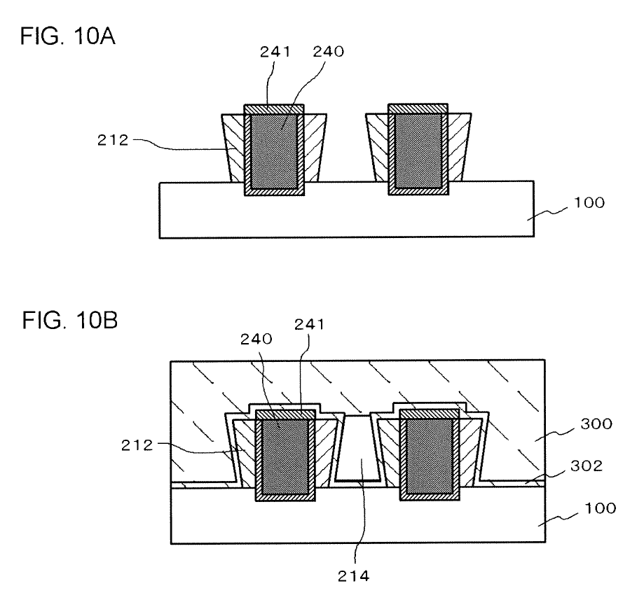

Thereafter, as shown in FIG. 10A, the insulating film 210 is removed by wet etching. In this process, the erroneously selected metals 243 are also removed.

Thereafter, as shown in FIG. 10B, the insulating film 302, the insulating interlayer 300, and the air gap 214 are formed. A method of forming them is the same as that of the first embodiment.

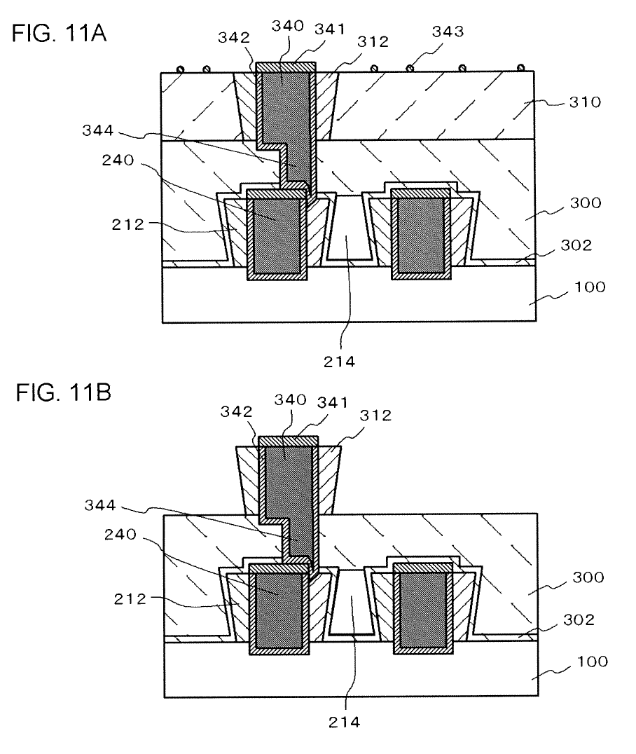

Next, as shown in FIG. 11A, the insulating film 310, the interconnect 340, the via 344, the barrier metal film 342, and the sidewall insulating film 312 are formed. A method of forming them is the same as that of the first embodiment.

Next, the cap metal film 341 is formed on the interconnect 340 using a selective CVD method. A material of the cap metal film 341 and a forming method thereof are the same as those of the cap metal film 241. In this process, erroneously selected metals 343 may be formed on the insulating film 310.

Thereafter, as shown in FIG. 11A, the insulating film 310 is removed by wet etching. In this process, the erroneously selected metals 343 are also removed.

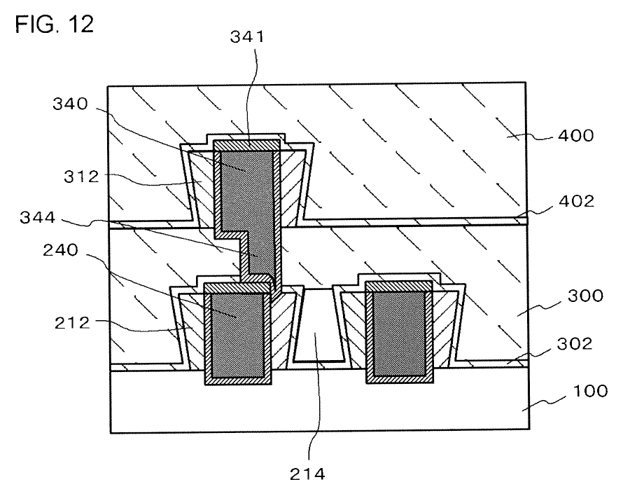

Thereafter, as shown in FIG. 12, the insulating film 402 and the insulating interlayer 400 are form. A method of forming them is the same as that of the first embodiment.

Even in the embodiment, the same effect as that of the first embodiment can be obtained. In addition, the erroneously selected metals 243, 343 may be formed at the time of forming the cap metal films 241 and 341 on the interconnects 240 and 340. However, the metals 243 and 343 are removed together with the insulating films 210 and 310, and thus hardly remain in the semiconductor device. Therefore, reliability of the semiconductor device is improved.

As described above, although the embodiments of the invention have been set forth with reference to the drawings, they are merely illustrative of the invention, and various configurations other than those stated above can be adopted.

It is apparent that the present invention is not limited to the above embodiment, and may be modified and changed without departing from the scope and spirit of the invention.

What is claimed is:

1. A semiconductor device comprising:
a plurality of interconnects extending parallel to each other;
sidewall insulating films formed at sidewalls of each of the plurality of interconnects;
an air gap, formed between each of the plurality of interconnects, which is located between a plurality of sidewall insulating films;
an insulating film formed over the plurality of interconnects, the plurality of sidewall insulating films and the air gap; and
a via, passing through the insulating film, which is connected to any of the interconnects,
wherein the sidewall insulating film is formed of a material having an etching rate lower than that of the insulating film in the conditions in which the insulating film is etched.

2. The semiconductor device according to claim 1, wherein the upper end of the sidewall insulating film is flat, and is larger in width than the lower end of the sidewall insulating film.

3. The semiconductor device according to claim 2, wherein the upper surfaces of the sidewall insulating film and the interconnect are formed to be coplanar with each other.

4. The semiconductor device according to claim 1, wherein the sidewall insulating film is a film obtained by oxidizing a hydrogenated siloxane film.

5. The semiconductor device according to claim 1, further comprising a cap metal film that covers the upper surface of the interconnect.

6. A method of manufacturing a semiconductor device, comprising:
forming a second insulating film over a first insulating film;
forming a plurality of interconnect trenches extending parallel to each other on the second insulating film, and forming an altered film by altering sidewalls of the plurality of interconnect trenches;
forming a plurality of interconnects by burying a conductive film in the plurality of interconnect trenches;
removing the second insulating film by etching, and leaving the altered film in sidewalls of the interconnects;
forming an insulating film over the first insulating film, the plurality of interconnects, and the altered film, and forming an air gap between the plurality of interconnects; and
forming a via, passing through the insulating film, which is connected to any of the interconnects,
wherein the altered film is formed of a material having an etching rate lower than that of the insulating film in the conditions in which the insulating film is etched.

7. The method of manufacturing a semiconductor device according to claim 6, wherein said step of forming the plurality of interconnect trenches includes forming a mask pattern over the second insulating film and etching the second insulating film using the mask pattern as a mask, and
wherein in said step of forming the altered film, the mask pattern is removed by plasma treatment, and the altered film is formed by the plasma treatment.

8. The method of manufacturing a semiconductor device according to claim 7, wherein the second insulating film is formed using hydrogenated siloxane, and
wherein in the plasma treatment, an oxygen-containing gas enters into a plasma state.

9. The method of manufacturing a semiconductor device according to claim 6, further comprising forming a cap metal film that covers the upper surface of the interconnects by a selective CVD method, after said step of forming the plurality of interconnects and before said step of removing the second insulating film.
